(19) United States
(12) Patent Application Publication
(10) Pub. No.: US 2014/0348196 A1
(43) Pub. Date: Nov. 27, 2014

(54) SEMICONDUCTOR OPTICAL DEVICE ASSEMBLY

(71) Applicant: SUMITOMO ELECTRIC INDUSTRIES, LTD., Osaka (JP)

(72) Inventors: Hiroyuki Yoshinaga, Yokohama-shi (JP); Michio Murata, Yokohama- shi (JP)

(21) Appl. No.: 14/283,972

(22) Filed: May 21, 2014

(30) Foreign Application Priority Data
May 22, 2013 (JP) 2013-0108098

(51) Int. Cl. H01S 5/34; H01S 5/227

(52) U.S. Cl. CPC H01S 5/3401; H01S 5/227
USPC 372/45.01

(57) ABSTRACT

A semiconductor optical device assembly includes a quantum cascade laser including first to fifth portions; and a sub-mount having a mount surface including first to third areas, the first area and the third area supporting the first portion and the fifth portion of the quantum cascade laser. The quantum cascade laser includes a substrate having a main surface; a semiconductor mesa disposed on the main surface in the third portion, the semiconductor mesa including a light emitting layer; and an electrode disposed on a surface in the first to fifth portions of quantum cascade laser, the electrode being in contact with an upper surface of the semiconductor mesa. The quantum cascade laser is mounted on the sub-mount with a gap formed between a surface of the electrode of the third portion of the quantum cascade laser and the second area of the sub-mount.

### BACKGROUND OF THE INVENTION

1. Field of the Invention

The present invention relates to a semiconductor optical device assembly.

2. Description of the Related Art

Japanese Unexamined Patent Application Publication No. 2003-332676 describes a semiconductor optical device having a structure that prevents damage to a waveguide region in a manufacturing process and a mounting process. The semiconductor optical device includes a waveguide region disposed between a pair of mesa grooves. A first mount region and a second mount region are disposed outside of the mesa grooves. A first spacer layer and a second spacer layer are respectively disposed in the first mount region and the second mount region. A first metal layer is electrically connected to an upper cladding layer of the waveguide region, and the first metal layer extends from an upper part of the waveguide region to an upper part of the first mount region. A second metal layer is disposed on an upper part of the second mount region. The height from the back surface of the semiconductor substrate to the upper end of the first metal layer of the waveguide region is less than the height from the back surface of the semiconductor substrate to the upper end of the first metal layer of the first mount region and the height from the back surface of the semiconductor substrate to the upper end of the second metal layer of the second mount region.

A quantum cascade laser (QCL) has an active layer (light emitting layer) in which a plurality of quantum well structures are stacked. The quantum cascade laser emits light of a mid-infrared wavelength range of approximately 3 μm to 20 μm. The quantum cascade laser has an operating voltage higher than that of a conventional semiconductor laser using for optical fiber communications which typically emits light having an emitting wavelength of 1.3 μm to 1.55 μm, and is, for example, 10 volts or higher. In addition to the high operating voltage, the threshold current of a quantum cascade laser is large, and is, for example, about 1 ampere. As a result, the amount of heat generated in the light emitting layer is about several tens of watts. This amount of generated heat is considerably larger than that of the semiconductor laser using for optical fiber communications.

### SUMMARY OF THE INVENTION

The quantum cascade laser emits light having a mid-infrared wavelength range of 3 μm to 20 μm. In order to confine light having such a long wavelength in a laser cavity including a light emitting layer, the laser cavity has a large volume. In addition, the gain per unit length of a light emitting layer of the quantum cascade laser is less than that of the semiconductor laser using for optical fiber communications. Therefore, the quantum cascade laser has a cavity length longer than that of the semiconductor laser using for optical fiber communications to obtain a gain for laser oscillation. Using such a long laser cavity leads to an increase in the volume of a light emitting layer.

In order to dissipate heat generated in an active layer, the quantum cascade laser is usually mounted on a sub-mount with its face down. However, when the quantum cascade laser is mounted on the sub-mount with its face down, a large stress tends to be generated in the active layer of the quantum cascade laser. The quantum cascade laser is easily affected by the stress in a mounting process because the active layer of the quantum cascade laser includes a multi quantum well (MQW) structure. As a result, the degradation in device characteristics of the quantum cascade laser occurs. Furthermore, the reliability of the quantum cascade laser also decreases due to the heat and stress in the active layer.

As described above, a quantum cascade laser consumes more electric power than, for example, a semiconductor laser using for optical fiber communications. The volume of an active layer of the quantum cascade laser is large. For these reasons, the quantum cascade laser is affected by a large amount of heat and stress that are generated in the active layer. Hence, it is necessary to reduce the effect of heat and stress in the active layer.

A semiconductor optical device assembly according to the present invention includes a quantum cascade laser including a first portion, a second portion, a third portion, a fourth portion, and a fifth portion that are sequentially arranged in a first direction; and a sub-mount having a mount surface including a first area, a second area, and a third area that are sequentially arranged in the first direction, the first area and the third area supporting the first portion and the fifth portion of the quantum cascade laser. The quantum cascade laser includes a substrate having a main surface, the substrate being made of a first conductive type semiconductor; a semiconductor mesa disposed on the main surface of the substrate in the third portion, the semiconductor mesa extending in a second direction that intersects the first direction, the semiconductor mesa including a light emitting layer and a first conductive type semiconductor layer disposed on the light emitting layer; and an electrode extending in the first portion, the second portion, the third portion, the fourth portion, and the fifth portion of quantum cascade laser, the electrode being in contact with an upper surface of the semiconductor mesa. The electrode in the first portion and the fifth portion of the quantum cascade laser is in contact with the first area and the third area of the sub-mount. In addition, the quantum cascade laser is mounted on the sub-mount with a gap formed between a surface of the electrode of the third portion of the quantum cascade laser and the second area of the sub-mount.

According to the semiconductor optical device assembly, the electrode extends in the first portion, the second portion, the third portion, the fourth portion, and the fifth portion of the quantum cascade laser. The electrode is in contact with the upper surface of the semiconductor mesa disposed on the main surface of the substrate in the third portion. The first portion and the fifth portion of the quantum cascade laser are supported by the first area and the third area of the sub-mount. A gap is formed between the third portion of the quantum cascade laser and the second area of the sub-mount. Therefore, heat generated in the semiconductor mesa during operation is transferred through the electrode, which continuously extends over the first portion, the second portion, the third portion, the fourth portion, and the fifth portion of the quantum cascade laser. Moreover, heat generated in the semiconductor mesa is dissipated from the first portion and the fifth portion of the quantum cascade laser to the first area and the third area of the sub-mount. In addition, the semiconductor mesa is prevented from directly receiving a stress (for example, thermal stress) from the sub-mount.

In the semiconductor optical device assembly according to the present invention, the quantum cascade laser preferably includes a trench in each of the second portion and the fourth portion. The trench extends in the second direction. The semiconductor mesa is defined by the trenches in the second portion and the fourth portion.

In the semiconductor optical device assembly according to the present invention, the quantum cascade laser preferably includes an insulating layer disposed on the substrate and on a side surface and the upper surface of the semiconductor mesa. The electrode is disposed on the insulating layer. The insulating layer has an opening on the upper surface of the semiconductor mesa. In addition, the electrode is in contact with the upper surface of the semiconductor mesa through the opening of the insulating layer.

In the semiconductor optical device assembly according to the present invention, the quantum cascade laser preferably includes terrace portions disposed on the main surface of the substrate in the first portion and the fifth portion, respectively. The terrace portion includes the light emitting layer and the first conductive type semiconductor layer. The insulating layer is disposed on the terrace portion. The quantum cascade laser has a distance between the main surface of the substrate and the insulating layer in the first portion and the fifth portion that is substantially equal to a distance between the main surface of the substrate and the electrode in the third portion.

According to the semiconductor optical device assembly, the quantum cascade laser is configured so that the distances between the electrode and the main surface of the substrate in the first portion, the third portion, and the fifth portion are substantially equal to one another, excluding the thickness of the insulating layer disposed on the terrace portion. The terrace portion has substantially the same structure as that of the semiconductor mesa which includes the light emitting layer and the first conductive type semiconductor layer. Therefore, in order to form a gap between the third portion of the quantum cascade laser and the second area of the sub-mount, it is not necessary to make a structural difference among the first portion, the fifth portion, and the third portion, concerning a structure that serves as a base of the electrode of the quantum cascade laser.

In the semiconductor optical device assembly according to the present invention, preferably, the electrode in the first portion and the fifth portion of the quantum cascade laser has a thickness greater than a thickness of the electrode in the third portion of the quantum cascade laser.

According to the semiconductor optical device assembly, the thickness of the electrode in the first portion and the fifth portion of the quantum cascade laser is larger than the thickness of the electrode in the third portion of the quantum cascade laser, and a gap is formed between the third portion of the quantum cascade laser and the second area of the sub-mount.

In the semiconductor optical device assembly according to the present invention, preferably, the electrode in the third portion of the quantum cascade laser includes a first plating layer. The electrode in the first portion and the fifth portion of the quantum cascade laser includes the first plating layer and a second plating layer disposed on the first plating layer. The gap is formed between the first plating layer in the third portion of the quantum cascade laser and the second area of the sub-mount.

According to the semiconductor optical device assembly, the electrode in the first portion and the fifth portion of the quantum cascade laser includes the first plating layer and the second plating layer. On the other hand, the third portion does not include the second plating layer. Accordingly, the thickness of the electrode in the first portion and the fifth portion of the quantum cascade laser is greater than the thickness of the electrode in the third portion of the quantum cascade laser. Thus, the gap is formed between the third portion of the quantum cascade laser and the second area of the sub-mount.

In the semiconductor optical device assembly according to the present invention, preferably, the second area of the sub-mount includes a groove that is recessed from surfaces of the first area and the third area. The semiconductor mesa of the quantum cascade laser is aligned with the groove.

According to the semiconductor optical device assembly, the second area of the sub-mount includes the groove that is recessed from the surfaces of the first area and the third area. Hence, the gap is formed between the third portion of the quantum cascade laser and the second area of the sub-mount.

The semiconductor optical device assembly according to the present invention may further include a solder member disposed on each of the first area and the third area of the sub-mount. The first portion and the fifth portion of the quantum cascade laser are preferably supported by the first area and the third area of the sub-mount via the solder member.

According to the semiconductor optical device assembly, the solder member is disposed between the electrode in the first portion and the fifth portion of the quantum cascade laser and electrode patterns on the first area and the third area of the sub-mount. By supporting the first portion and the fifth portion of the quantum cascade laser with the first area and the third area of the sub-mount, the gap is formed between the third portion of the quantum cascade laser and the second area of the sub-mount. As a result, a stress (for example, thermal stress) generated in the mounting process is not applied to the semiconductor mesa.

In the semiconductor optical device assembly according to the present invention, preferably, the electrode extends in the first direction in the first portion, the third portion, and the fifth portion of the quantum cascade laser. The electrode in the first portion and the fifth portion of the quantum cascade laser has a length that is equal to or greater than a length of the electrode in the third portion of the quantum cascade laser in the first direction.

According to the semiconductor optical device assembly, with respect to the first direction, the length of the electrode in the first portion and the fifth portion of the quantum cascade laser is equal to or greater than the length of the electrode in the third portion of the quantum cascade laser. Thus, heat generated in the semiconductor mesa is dissipated to the first area and the third area of the sub-mount through the electrode of the first portion and the fifth portion, which has a length that is equal to or greater than a length of the electrode on the semiconductor mesa in the third portion of the quantum cascade laser.

In the semiconductor optical device assembly according to the present invention, preferably, the quantum cascade laser further includes a trench in each of the second portion and the fourth portion, the trench defining the semiconductor mesa, and an insulating layer disposed on the substrate, a side surface of the trench, and a side surface and the upper surface of the semiconductor mesa, the insulating layer having an opening on the upper surface of the semiconductor mesa. The electrode is formed on the insulating layer, the electrode being contact with the upper surface of the semiconductor mesa through the opening. In addition, the electrode in the second portion and the fourth portion of the quantum cascade laser has a length that is equal to or greater than a length of the electrode in the third portion of the quantum cascade laser in the first direction.

In the semiconductor optical device assembly according to the present invention, preferably, the substrate of the quantum cascade laser includes a first cladding region made of the first conductive type semiconductor. The first conductive type semiconductor layer of the semiconductor mesa includes a second cladding region. The trench reaches the first cladding region of the substrate. In addition, the first cladding region, the light emitting layer, and the second cladding region are located at the side surface of the trench.

According to the semiconductor optical device assembly, the first cladding region, the light emitting layer, and the second cladding region reach the side surfaces of the trench grooves. Accordingly, heat from these semiconductor regions is transferred to the electrode on the side surfaces of the trench grooves through an insulating film, and is dissipated.

In the semiconductor optical device assembly according to the present invention, preferably, the semiconductor mesa has a width in the range of 5 μm to 20 μm. The substrate may be made of InP, and the sub-mount may be made of AlN.

### BRIEF DESCRIPTION OF THE DRAWINGS

FIG. 1A is a plan view illustrating a quantum cascade laser.

FIG. 1B is a plan view illustrating a sub-mount.

FIG. 2 is a sectional view illustrating a semiconductor optical device assembly in which the quantum cascade laser illustrated in FIG. 1A is mounted on the sub-mount illustrated in FIG. 1B.

FIG. 3A is a plan view illustrating a quantum cascade laser.

FIG. 3B is a plan view illustrating a sub-mount.

FIG. 4 is a sectional view illustrating a semiconductor optical device assembly in which the quantum cascade laser illustrated in FIG. 3A is mounted on the sub-mount illustrated in FIG. 3B.

FIG. 5 shows a scanning electron microscope (SEM) image of a quantum cascade laser according to the present embodiment.

FIGS. 6A to 6D illustrate examples of a quantum cascade laser according to the present embodiment used in thermal analyses.

### DESCRIPTION OF THE PREFERRED EMBODIMENTS

Hereinafter, embodiments of a semiconductor optical device assembly according to the present invention will be described with reference to the attached drawings. Where possible, the same portions will be denoted by the same numerals.

### First Embodiment

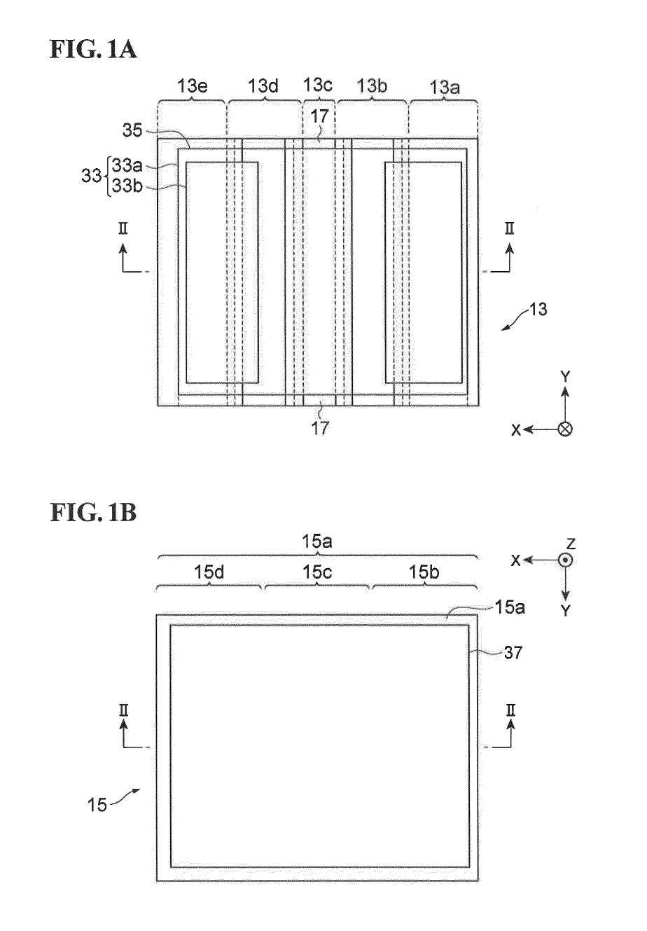

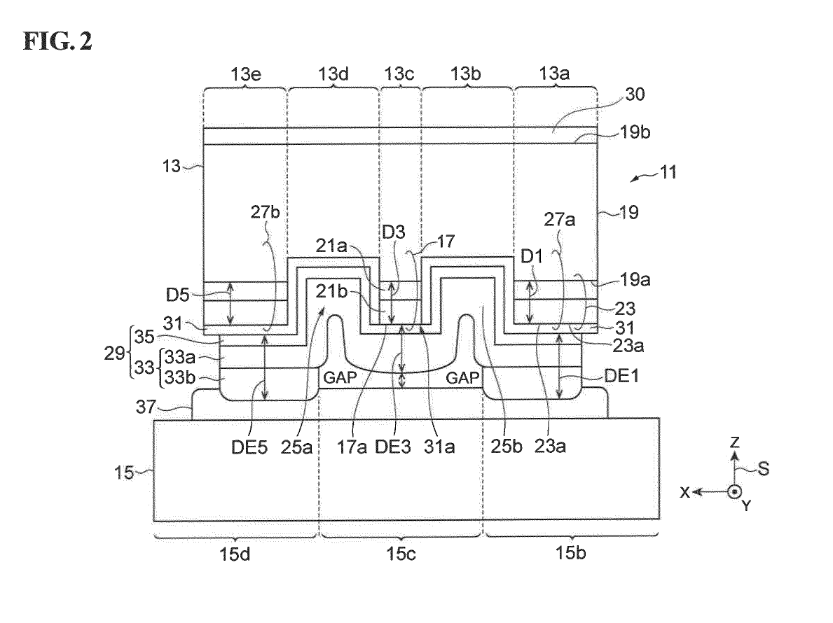

FIG. 1A is a plan view illustrating a quantum cascade laser. FIG. 1B is a plan view illustrating a sub-mount. FIG. 2 is a sectional view illustrating a semiconductor optical device assembly in which the quantum cascade laser illustrated in FIG. 1A is mounted on the sub-mount illustrated in FIG. 1B. FIG. 2 shows a sectional view taken along line II-II of FIGS. 1A and 1B. In each of FIGS. 1A, 1B, and 2, an orthogonal coordinate system S is shown to indicate the directions in the figure. A semiconductor optical device assembly 11 includes a quantum cascade laser 13 and a sub-mount 15. The sub-mount 15 has a mount surface 15a on which the quantum cascade laser 13 is mounted. The sub-mount 15 is made of a material that is different from a semiconductor. Therefore, the thermal expansion coefficient of the sub-mount 15 is different from the thermal expansion coefficient of the quantum cascade laser 13.

The quantum cascade laser 13 includes a first portion 13a, a second portion 13b, a third portion 13c, a fourth portion 13d, and a fifth portion 13e. The first portion 13a, the second portion 13b, the third portion 13c, the fourth portion 13d, and the fifth portion 13e are sequentially arranged in a first direction (for example, the X-axis direction). The first portion 13a, the second portion 13b, the third portion 13c, the fourth portion 13d, and the fifth portion 13e each extend in a second direction (for example, the Y-axis direction) that intersects the first direction. The third portion 13c of the quantum cascade laser 13 includes a semiconductor mesa 17 serving as a light emitting portion. The semiconductor mesa 17 extends in the second direction. The semiconductor mesa 17 includes a light emitting layer 21a and a semiconductor layer 21b of a first conductive type. In the embodiment, the first conductive type is an n-type. The second portion 13b and the fourth portion 13d of the quantum cascade laser 13 respectively include trenches 25a and 25b. The trenches 25a and 25b extend in the second direction. The first portion 13a and the fifth portion 13e of the quantum cascade laser 13 respectively include semiconductor terrace 27 (terrace portions 27a and 27b). The semiconductor terrace 27 (terrace portions 27a and 27b) extend in the second direction.

The quantum cascade laser 13 includes a substrate 19 and a stacked semiconductor layer 23. The substrate 19 is made of a semiconductor of a first conductive type (for example, n-type semiconductor). The substrate 19 has a main surface 19a and a back surface 19b. The stacked semiconductor layer 23 is disposed on the main surface 19a of the substrate 19. The stacked semiconductor layer 23 includes the light emitting layer 21a and the semiconductor layer 21b of the first conductive type. The light emitting layer 21a includes a multi quantum well (MQW) structure. The semiconductor layer 21b includes a cladding layer of the first conductive type and a contact layer of the first conductive type. The first portion 13a, the second portion 13b, the third portion 13c, the fourth portion 13d, and the fifth portion 13e of the quantum cascade laser 13 include an electrode 29. The electrode 29 is in contact with an upper surface 17a of the semiconductor mesa 17. Each of the first portion 13a, the third portion 13c, and the fifth portion 13e of the quantum cascade laser 13 includes a portion of the substrate 19, a portion of the stacked semiconductor layer 23, and a portion of the electrode 29. Each of the second portion 13b and the fourth portion 13d of the quantum cascade laser 13 includes a portion of the substrate 19 and a portion of the electrode 29. Each of the second portion 13b and the fourth portion 13d of the quantum cascade laser 13 may further include a portion of the stacked semiconductor layer 23. A back surface wiring metal 30 is formed on the back surface 19b of the substrate 19.

The mount surface 15a of the sub-mount 15 includes a first area 15b, a second area 15c, and a third area 15d. The first area 15b, the second area 15c, and the third area 15d are sequentially arranged in the first direction (the X-axis direction). The first area 15b and the third area 15d of the sub-mount 15 support the first portion 13a and the fifth portion 13e of the quantum cascade laser 13. In the present embodiment, this support is performed via a solder member 37 (made of, for example, AuSn solder or In solder). The solder member 37 is disposed so as to extend over the first to third areas 15b to 15d of the sub-mount 15. However, the solder member 37 may be disposed on the first area 15b and the third area 15d of the sub-mount 15.

The quantum cascade laser 13 and the sub-mount 15 are arranged in a third direction (the Z-axis direction). The quantum cascade laser 13 is mounted on the sub-mount 15. A gap GAP is formed between the third portion 13c of the quantum cascade laser 13 and the second area 15c of the sub-mount 15.

According to the semiconductor optical device assembly 11, the electrode 29, which is in contact with the upper surface 17a of the semiconductor mesa 17, extends over the first portion 13a, the second portion 13b, the third portion 13c, the fourth portion 13d, and the fifth portion 13e of the quantum cascade laser 13. The first portion 13a and the fifth portion 13e of the quantum cascade laser 13 are supported by the first area 15b and the third area 15d of the sub-mount 15. The third portion 13c of the quantum cascade laser 13 is disposed on the sub-mount 15 with the gap GAP between the second area 15c of the sub-mount 15 and the third portion 13c. Therefore, the semiconductor mesa 17 can be prevented from directly receiving a thermal stress from the sub-mount 15. The sub-mount 15 is made of a material that is different from a semiconductor. In the present embodiment, the sub-mount 15 is made of a material that has a thermal conductivity higher than that of a semiconductor. Heat generated in the semiconductor mesa during operation is transferred through the electrode 29, which continuously extends over the first portion 13a, the second portion 13b, the third portion 13c, the fourth portion 13d, and the fifth portion 13e of the quantum cascade laser 13. Moreover, heat generated in the semiconductor mesa is dissipated from the first portion 13a and the fifth portion 13e of the quantum cascade laser 13 to the first area 15b and the third area 15d of the sub-mount 15.

As illustrated in FIG. 2, in the quantum cascade laser 13 of the semiconductor optical device assembly 11, the thicknesses of the stacked semiconductor layer 23 in the first portion 13a, the third portion 13c, and the fifth portion 13e are substantially equal to each other. The first portion 13a, the third portion 13c, and the fifth portion 13e of the quantum cascade laser 13 include the light emitting layer 21a and the semiconductor layer 21b of the stacked semiconductor layer 23, the semiconductor layer 21b being disposed on the light emitting layer 21a. Moreover, the electrode 29 includes a gold (Au) plating layer.

According to the semiconductor optical device assembly 11, the quantum cascade laser 13 is configured so that the distances between the main surface 19a of the substrate 19 and the electrode 29 in the first portion 13a, the third portion 13c, and the fifth portion 13e are substantially equal. Therefore, in order to form the gap GAP between the third portion 13c of the quantum cascade laser 13 and the second area 15c of the sub-mount 15, it is not necessary to make a difference among the first portion 13a, the fifth portion 13e, and the third portion 13c, concerning a structure that serves as a base of the electrode 29 of the quantum cascade laser 13.

The quantum cascade laser 13 includes an insulating layer 31. The insulating layer 31 covers a surface 23a of the stacked semiconductor layer 23. Moreover, the insulating layer 31 has an opening 31a at the position of the upper surface 17a of the semiconductor mesa 17. The electrode 29 includes a metal layer 35 and a gold (Au) plating layer 33. In the first portion 13a, the second portion 13b, the fourth portion 13d, and the fifth portion 13e, the electrode 29 is in contact with the insulating layer 31. To be specific, the metal layer 35 is in contact with the insulating layer 31. In the third portion 13c, the metal layer 35 of the electrode 29 forms ohmic contact with the semiconductor layer 21b. In the embodiment, the metal layer 35 of the electrode 29 forms ohmic contact with the contact layer in the semiconductor layer 21b. In addition, the stacked semiconductor layer 23 of the first portion 13a and the fifth portion 13e have the same structure as that of the stacked semiconductor layer 23 of the third portion 13c, and includes the light emitting layer 21a and the semiconductor layer 21b. Hence, in the quantum cascade laser 13, the distances D1 and D5 between the substrate main surface 19a and the insulating layer 31 in the first portion 13a and the fifth portion 13e are substantially equal to the distance D3 between the substrate main surface 19a (the upper surface 17a of the semiconductor mesa 17) and the electrode 29 in the third portion 13c. According to the semiconductor optical device assembly 11, in the quantum cascade laser 13, the distances between the electrode 29 and the substrate main surface 19a in the first portion 13a, the third portion 13c, and the fifth portion 13e may be made substantially equal to one another, excluding the thickness of the insulating layer 31 covering the surface 23a of the stacked semiconductor layer 23. Therefore, in order to form the gap GAP between the third portion 13c of the quantum cascade laser 13 and the second area 15c of the sub-mount 15, it is not necessary to make a structural difference among the first portion 13a, the fifth portion 13e, and the third portion 13c, concerning a structure that serves a base of the electrode 29 of the quantum cascade laser 13. In the embodiment, the gap GAP between the third portion 13c of the quantum cascade laser 13 and the second area 15c of the sub-mount 15 is formed by make a difference in the thickness of the electrode 29 between the first and fifth portions 13a and 13e and the third portion 13c of the quantum cascade laser 13 as described below. The thickness of the insulating layer 31 on the first portion 13a and the fifth portion 13e are substantially equal to the thickness of the insulating layer 31 on the second portion 13b and the fourth portion 13d, excluding variance that occurs during deposition.

Regarding the thickness of the electrode 29, the thickness DE1 of the electrode 29 of the first portion 13a and the thickness DE5 of the electrode 29 of the fifth portion 13e are greater than the thickness DE3 of the electrode 29 of the third portion 13c. To achieve this configuration, in the present embodiment, the electrode 29 in the first portion 13a and the fifth portion 13e each include a first plating layer 33a and a second plating layer 33b. The electrode 29 of the third portion 13c includes the first plating layer 33a. The surface of the first plating layer 33a of the third portion 13c is exposed to the outside. By using a plurality of plating layers, including the plating layer 33b in addition to the plating layer 33a, the thickness of the electrode 29 in the first portion 13a and the fifth portion 13e of the quantum cascade laser 13 is made greater than the thickness of the electrode 29 in the third portion 13c. By mounting the quantum cascade laser 13 on the sub-mount 15, the gap GAP is formed between the third portion 13c of the quantum cascade laser 13 and the second area 15c of the sub-mount 15 because the quantum cascade laser 13 has the thickness of the electrode 29 in the first portion 13a and the fifth portion 13e greater than the thickness of the electrode 29 in the third portion 13c.

In the semiconductor optical device assembly 11 according to the present embodiment, the quantum cascade laser 13 is mounted on the sub-mount 15 with its face down. Hence, the thermal resistance of the semiconductor optical device assembly 11 is reduced. Moreover, when mounting the quantum cascade laser 13 on the sub-mount 15 with its face down, a stress applied to the quantum cascade laser 13 is also reduced. As a result, degradation of the characteristics of the light emitting layer, which is caused by the stress applied to the quantum cascade laser 13, is reduced. Thus, the semiconductor optical device assembly 11 having high reliability may be provided. To be specific, the quantum cascade laser 13 is mounted on a mount base member, such as the sub-mount 15, via a solder member. The quantum cascade laser 13 has a mesa portion and terrace portions. The mesa portion includes the light emitting portion. The mesa portion and the terrace portions are formed on a semiconductor substrate. The terrace portions of the quantum cascade laser 13 are fixed to the sub-mount 15 via a solder member. An air gap GAP exists between the electrode of the mesa portion of the quantum cascade laser 13 and the sub-mount 15.

A method for fabricating the semiconductor optical device assembly 11 will be described below. First, a quantum cascade laser is fabricated. In the present embodiment, a multi quantum well (MQW) structure made of GaInAs/AlInAs is grown on an n-type InP substrate by using a metal-organic vapor phase epitaxy (MOVPE) method. An n-type InP cladding layer and an n-type GaInAs contact layer are grown on the multi quantum well (MQW) structure to form a stacked semiconductor layer. The thickness of the stacked semiconductor layer is, for example, 4 μm to 6 μm. The typical thickness of the stacked semiconductor layer is, for example, 5 μm. After forming a resist on the n-type GaInAs contact layer, a resist mask is formed by photolithography. By using the resist mask, the stacked semiconductor layer is etched by reactive ion etching (RIE) to form a mesa portion and terrace portions in a stripe pattern. The width of the mesa portion is, for example, 5 μm to 20 μm. The typical width of the mesa portion is, for example, 10 μm. The width of each trench between a corresponding one of terrace portions and the mesa portion is, for example, 10 μm to 30 μm, and the typical width of the trench is 20 μm. The bottom of the trench reaches the n-type InP substrate. The depth of the trench is, for example, 6 μm to 10 μm, and the typical depth is 6 μm. After forming the mesa, a protective film made of SiON is formed on the substrate. By photolithography and reactive ion etching (RIE), an opening is formed in the protective film on the upper surface the mesa portion. As a wiring metal and an ohmic metal, a metal layer made of, for example, Ti/Pt/Au is formed on the protective film and in the opening of the protective film on the upper surface the mesa portion by using an evaporation method. Subsequently, a first plating layer (having a thickness of, for example, 3 μm to 5 μm) is formed on the metal layer (wiring metal and ohmic metal). In the present embodiment, a first plating layer made of Au and having a thickness of 5 μm is formed. Subsequently, a resist mask that partially covers the mesa portion and the trenches is formed by photolithography. By using the resist mask, a second plating layer (having a thickness of, for example, 3 μm to 5 μm) is formed. The lower limit of the thickness of the second plating layer is set at 3 μm in order to avoid degradation of heat dissipation performance. On the other hand, there is no particular limitation on the upper limit for the thickness of the second plating layer. However, in the present embodiment, the upper limit of the thickness of the second plating layer is set at 5 μm in order to prevent a plating stress from becoming too large. In the present embodiment, a second plating layer made of Au and having a thickness of 5 μm is formed. After forming the plating layer, the thickness of the n-type InP substrate is reduced to 100 μm by polishing, for example. Subsequently, a back surface wiring metal is formed on the back surface (polished surface) of the n-type InP substrate. The back surface wiring metal is made of, for example, AuGe/Ni/Au.

Subsequently, a quantum cascade laser chip having mirror surfaces at both end facets of the mesa portion is formed by cleaving the substrate. The end facets having the mirror surfaces constitute a laser cavity. The typical length of the chip in the longitudinal direction of the laser cavity that is a distance between the end facets is 2 mm, and the typical width of the chip is 0.5 mm.

Next, a solder member (made of, for example, AuSn) is placed on a sub-mount made of AlN. The thickness of the solder member before being melted is, for example, 1 μm to 5 μm. While pressing the chip with a collet, the sub-mount and the solder member are heated. When the solder member is melted, the chip of the quantum cascade laser is mounted on the sub-mount with its face down. At this time, the sub-mount and the solder member are heated to a temperature of 300 degrees or higher and 400 degrees or lower (for example, 320 degrees). In the embodiment, the sub-mount and the solder member are heated to a temperature of, for example, 320 degrees. As the temperature of the sub-mount and the solder member is decreased to room temperature, die bonding is finished, and the solder member of the sub-mount is connected to the second Au plating layer of the quantum cascade laser chip. On the other hand, the first Au plating layer on the mesa portion of the quantum cascade laser chip is separated from the surface of the sub-mount and the solder member on the sub-mount by a predetermined distance corresponding to the air gap GAP. The initial thickness of the solder member is 3 μm. However, because the second Au plating layer sinks into the solder member, the thickness of the solder member around the second Au plating layer is increased. On the other hand, the second Au plating layer is not present on the mesa portion. Hence, in contrast to the terrace portions, an air gap corresponding to the thickness of the second Au plating layer is formed on the mesa portion. Accordingly, the electrode of the mesa portion does not contact the solder member. Subsequently, wire bonding is performed on the back surface electrode. When an electric current is passed between the sub-mount and the wire, the quantum cascade laser emits light. In the present embodiment, the emission wavelength of the quantum cascade laser is about 8 μm. The driving current is 1.5 amperes, and the voltage at this time is 8 volts. According to the present embodiment, the gap GAP is adjusted by adjusting the plating thickness in the step of forming the second plating layer in the semiconductor chip fabrication process. In the semiconductor chip, second plating layers are disposed on both sides of the semiconductor mesa with a distance therebetween. Thus, stresses applied from two fixing portions are dispersed over the entire chip. The distance between the second plating layers is, for example, 5 μm to 50 μm.

In the first embodiment, the electrode on the mesa portion is not connected to the solder member of the sub-mount. When an electrode on a mesa portion is connected to a solder member on a sub-mount, a stress is applied to the mesa portion including the active layer (light emitting layer). The stress is mainly generated in a mounting process when a solder member made of, for example, AuSn is solidified and contracted by being cooled from a melted state. The stress applied to the light emitting layer of the quantum cascade laser may cause a crystal defect in the light emitting layer. In the present embodiment, the mesa portion is not in direct contact with the solder member. Hence, a stress generated by contraction of the solder member is not applied to the mesa portion. In addition, the electric power consumption of the quantum cascade laser according to the present embodiment is higher than that of a conventional semiconductor laser including a p-n junction using for optical fiber communications. Such high electric power consumption causes the mesa portion to generate a large amount of heat and increases the temperature of the mesa portion. The heat generation and the temperature increase in the mesa portion increase the influence of the stress on the light emitting layer. In the present embodiment, the stress is not directly applied to the mesa portion, because the mesa portion is not in direct contact with the solder member and the sub-mount. Hence, even though the electric power consumption of the quantum cascade laser is high, degradation of the characteristics and reduction in the reliability due to stress applied to the mesa portion can be suppressed. Heat generated in the mesa portion is transferred through the first Au plating layer, the second Au plating layer, and the solder member; and the heat is dissipated to the sub-mount. As an example of other mounting structures, a semiconductor laser is mounted on a sub-mount with its face up by fixing a back surface metal of the semiconductor laser by using a solder member. With this structure, in which the semiconductor laser is mounted on the sub-mount with its face up, heat generated in a mesa portion in accordance with the high electric power consumption is discharged through an n-type InP substrate, which has a high thermal resistance. For this reason, heat dissipation performance is low, and the characteristics of the semiconductor laser, in particular, operation at a high temperature and at a high power may become degraded. In contrast, according to the present embodiment, a heat dissipation path is formed through metal materials having high thermal conductivity. Moreover, the length of the heat path from the mesa portion to the mount base member is short. Therefore, a semiconductor optical device assembly having high heat dissipation performance and good characteristics even at a high temperature can be provided.

Instead of forming the second Au plating layer, an indium (In) layer may be formed on the terrace portions by using an evaporation method. A quantum cascade laser is formed through a process similar to that of the first embodiment. The thickness of the In layer is, for example, 5 μm. The quantum cascade laser is mounted on a sub-mount made of AlN and having a surface on which a gold (Au) film has been formed. In this case, a solder member made of AuSu is not used. Hence, the In layer is made to directly contact the sub-mount (mount base member) heated to a temperature in the range of 160° C. to 200° C. In the embodiment, the sub-mount is heated to a temperature of, for example, 170° C. The quantum cascade laser is mounted on the sub-mount, as In is melted by the heat of the sub-mount. The In layer is not formed on the electrode of the mesa portion. Accordingly, an air gap GAP is formed between the electrode of the mesa portion and the sub-mount. Thus, as in the first embodiment, degradation of the lasing characteristics of the quantum cascade laser is suppressed, and good high-temperature characteristics and high reliability are ensured. Indium (In) is a soft metal even at room temperature. Accordingly, by using an In layer, a stress due to the difference between the thermal expansion coefficients of the mount base member such as the sub-mount and the semiconductor laser is reduced. Therefore, In layer is preferably used for a quantum cascade laser having a long cavity length. As a result, the reliability of the quantum cascade laser may be improved.

Referring back to FIGS. 1A, 1B, and 2, the semiconductor optical device assembly 11 will be described. The electrode 29 extends in the first direction (the X-axis direction) in the first portion 13a, the third portion 13c, and the fifth portion 13e of the quantum cascade laser 13. Preferably, the length of the electrode 29 in the first portion 13a and the fifth portion 13e of the quantum cascade laser 13 in the first direction (the X-axis direction) is equal to or greater than the length of the electrode 29 in the third portion 13c of the quantum cascade laser 13. Hence, the electrode 29 having a length that is approximately equal to or greater than the length of the electrode 29 on the semiconductor mesa 17 is formed on each of the first portion 13a and the fifth portion 13e. Heat generated in the semiconductor mesa 17 is dissipated through these portions of the electrode (the electrode 29 on the first portion 13a and the fifth portion 13e) to the first area 15b and the third area 15d of the sub-mount 15.

In the semiconductor optical device assembly 11, the electrode 29 extends in the first direction (the X-axis direction) in the second portion 13b and the fourth portion 13d of the quantum cascade laser 13. Preferably, with respect to the first direction (the X-axis direction), the length of the electrode 29 in the second portion 13b and the fourth portion 13d of the quantum cascade laser 13 is equal to or greater than the length of the electrode 29 in the third portion 13c. The substrate 19 includes a first cladding region made of a semiconductor of the first conductive type. The semiconductor layer 21b of the semiconductor mesa 17 includes a second cladding region made of a semiconductor of the first conductive type. Side surfaces of the first cladding region, the light emitting layer, and the second cladding region, are located at side surfaces of the trenches 25a and 25b. The quantum cascade laser 13 includes the insulating layer 31, which serves as a protective film, disposed between the electrode 29 and the stacked semiconductor layer 23. The electrode 29 extends along the insulating layer 31 on the side surfaces of the trenches 25a and 25b. The thickness of the insulating layer 31 is, for example, 100 nm or greater and 500 nm or less.

According to the semiconductor optical device assembly 11, the side surfaces of the first cladding region, the light emitting layer, and the second cladding region in the semiconductor mesa 17 reach the side surfaces of the trenches 25a and 25b. Hence, heat generated in these semiconductor regions of the semiconductor mesa 17 is transferred through the insulating layer 31 to the electrode 29 on the side surfaces of the trenches. A second plating layer 33b may be disposed also in the trenches 25a and 25b. In this case, the heat dissipation performance of the quantum cascade laser 13 is further increased.

In the semiconductor optical device assembly 11, preferably, the gap GAP is, for example, 5 μm or greater. This is because the thickness of the AuSn solder is about 3 μm, and the AuSn solder becomes slightly melted and flows when heated. The trenches 25a and 25b reach the first cladding region of the substrate 19, which is located below the light emitting layer 21a. Preferably, the substrate 19 is made of InP. The sub-mount 15 may be made of AlN or the like. According to the semiconductor optical device assembly 11, when the gap GAP is 5 μm or greater, the gap GAP is easily formed in the manufacturing process.

### Second Embodiment

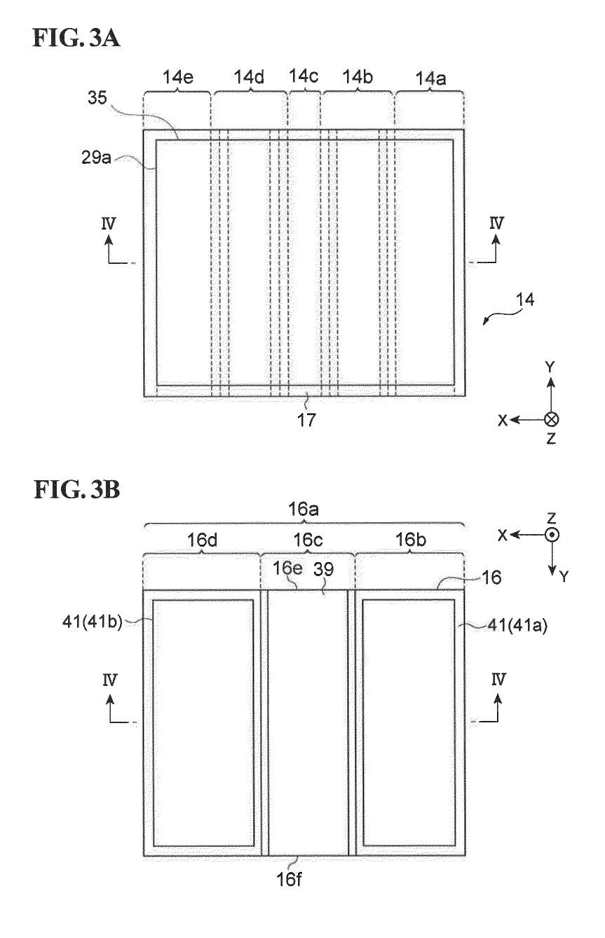

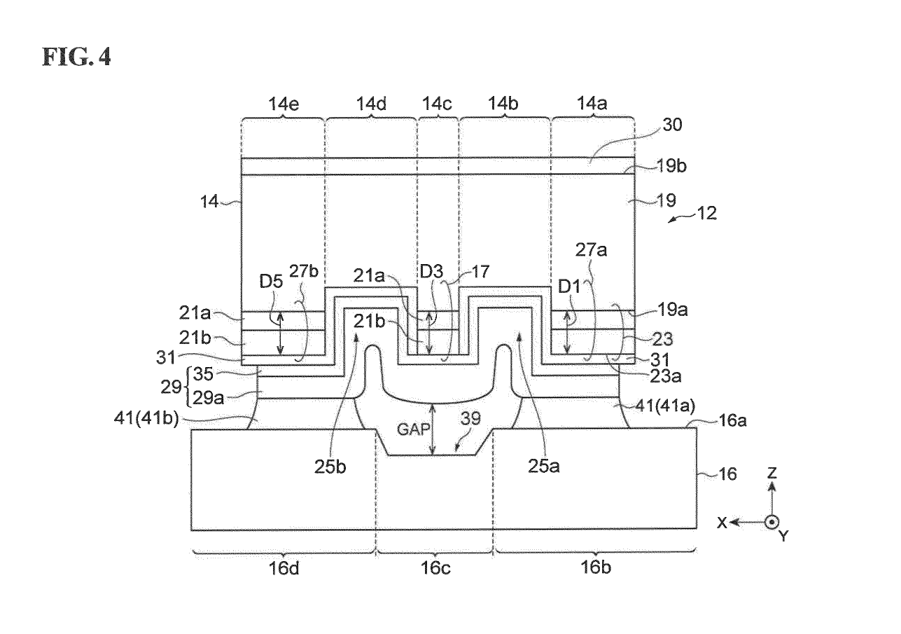

FIG. 3A is a plan view illustrating a quantum cascade laser. FIG. 3B is a plan view illustrating a sub-mount. FIG. 4 is a sectional view illustrating a semiconductor optical device assembly in which the quantum cascade laser illustrated in FIG. 3A is mounted on the sub-mount illustrated in FIG. 3B. FIG. 4 shows a sectional view taken along line IV-IV of FIGS. 3A and 3B. In each of FIGS. 3A, 3B, and 4, an orthogonal coordinate system S is shown to indicate the directions in the figure. A semiconductor optical device assembly 12 includes a quantum cascade laser 14 and a sub-mount 16. The sub-mount 16 has a mount surface 16a on which the quantum cascade laser 14 is mounted. The sub-mount 16 is made of a material that is different from a semiconductor. Therefore, the thermal expansion coefficient of the sub-mount 16 is different from the thermal expansion coefficient of the quantum cascade laser 14.

The quantum cascade laser 14 includes a first portion 14a, a second portion 14b, a third portion 14c, a fourth portion 14d, and a fifth portion 14e. In the quantum cascade laser 14, the electrode 29 of each of the first portion 14a and the fifth portion 14e includes a first plating layer 29a. The electrode 29 of the third portion 14c also includes the first plating layer 29a. The first portion 14a, the second portion 14b, the third portion 14c, the fourth portion 14d, and the fifth portion 14e may correspond to the first portion 13a, the second portion 13b, the third portion 13c, the fourth portion 13d, and the fifth portion 13e in the first embodiment. However, in the quantum cascade laser 14, the electrode 29 of each of the first portion 14a and the fifth portion 14e does not include a second plating layer corresponding to the second plating layer 33b of the quantum cascade laser 13 in the first embodiment. The sub-mount 16 has the mount surface 16a. The mount surface 16a has a first area 16b, a second area 16c, and a third area 16d, which respectively correspond to the first area 15b, the second area 15c, and the third area 15d of the mount surface 15a of the sub-mount 15 in the first embodiment. In the semiconductor optical device assembly 12, the second area 16c of the sub-mount 16 includes a groove 39. The groove 39 is recessed from the surfaces of the first area 16b and the third area 16d. The groove 39 extends in the second direction (the Y-axis direction). In the present embodiment, the groove 39 extends from an edge 16e to another edge 16f of the sub-mount 16. The other edge 16f of the sub-mount 16 is located opposite the 16e. The width of the groove 39 is greater than the width of the semiconductor mesa 17. Preferably, the width of the groove 39 is greater than the width of the semiconductor mesa 17 by 20 μm or more. Thus, even if the semiconductor mesa 17 and the sub-mount 16 are not accurately aligned with each other in the mounting process, the semiconductor mesa 17 is reliably positioned within the width of the groove 39. The depth of the groove 39 is, for example, about 5 μm to 10 μm. The width of the groove 39 is, for example, about 25 μm to 40 μm. The semiconductor mesa 17 of the quantum cascade laser 14 is aligned with the groove (recess) 39. According to the semiconductor optical device assembly 12, the second area 16c of the sub-mount 16 has the groove 39, which is recessed from the surfaces of the first area 16b and the third area 16d. Hence, a gap GAP is formed between the third portion 14c of the quantum cascade laser 14 and the second area 16c of the sub-mount 16.

In the semiconductor optical device assembly 12, a solder member 41 (made of, for example, AuSn) includes a first solder portion 41a and a second solder portion 41b, which are respectively disposed on the first area 16b and the third area 16d of the sub-mount 16. The first solder portion 41a and the second solder portion 41b are separated from each other with the groove 39 therebetween. The solder member may continuously extend over the first to third areas 16b to 16d of the sub-mount 16. The first portion 14a and the fifth portion 14e of the quantum cascade laser 14 are respectively supported by the first area 16b and the third area 16d of the sub-mount 16 via the solder portions 41a and 41b. According to the semiconductor optical device assembly 12, the solder member 41 is disposed between portions of the electrode 29 of the first portion 14a and the fifth portion 14e of the quantum cascade laser 14 and electrode patterns on the first area 16b and the third area 16d of the sub-mount 16. In the present embodiment, the sub-mount 16 has the groove 39, and therefore the gap GAP is formed between the third portion 14c of the quantum cascade laser 14 and the second area 16c of the sub-mount 16.

The sub-mount 16 may be used in combination with the quantum cascade laser 13. The gap GAP is formed between the third portion 13c of the quantum cascade laser 13 and the second area 16c of the sub-mount 16 owing to the thickness of the electrode 29 of the first portion 13a and the fifth portion 13e of the quantum cascade laser 13 and the recess of the groove 39 of the sub-mount 16.

Next, a method of fabricating the semiconductor optical device assembly 12 will be described. In the present embodiment, as in the first embodiment, a multi quantum well (MQW) structure made of GaInAs/AlInAs is grown on an n-type InP substrate by using a metal-organic vapor phase epitaxy (MOVPE) method. Subsequently, trenches, a semiconductor mesa, and the like are made as in the first embodiment. In forming an electrode, an ohmic electrode (metal layer 35) is formed as in the first embodiment, the first plating layer 29a is formed subsequently, and forming of the electrode is finished.

After the electrode has been formed, a quantum cascade laser chip is formed as in the first embodiment. In the present embodiment, a semiconductor laser chip has a structure the same as that of the first embodiment, except that the second plating layer is omitted. The mount surface of the sub-mount has a groove having a typical width of 30 μm and a depth of 5 μm.

A solder member (made of, for example, AuSn) is placed on the sub-mount, which is made of AlN. In the present embodiment, the solder member is formed in areas connected to the terrace portions. Alternatively, the solder member may be disposed over the entirety of the mount surface of the sub-mount. The quantum cascade laser chip is aligned so that the orientation and the position of the mesa portion correspond to the orientation and the position of the groove of the sub-mount. While pressing the chip with a collet, the sub-mount and the solder member are heated. When the solder member is melted, the chip of the quantum cascade laser is mounted on the sub-mount with its face down. At this time, the sub-mount and the solder member are heated to a temperature of 300 degrees or higher and 400 degrees or lower. In the embodiment, the sub-mount and the solder member are heated to a temperature of, for example, 320 degrees. As the temperature of the sub-mount and the solder member is decreased to room temperature, die bonding is finished. Thus, the solder member of the sub-mount is connected to a single Au plating layer of the quantum cascade laser chip. On the other hand, the surface of the Au plating layer on the mesa portion of the quantum cascade laser chip is separated from the surface of the sub-mount and the solder member on the sub-mount and forms the air gap GAP. The sub-mount and the quantum cascade laser chip are connected to each other via a solder member made of AuSn. Also with the present embodiment, a quantum cascade laser having good characteristics at a high temperature and high reliability can be provided.

Referring back to FIGS. 3A, 3B, and 4, the semiconductor optical device assembly 12 will be described. The electrode 29 extends in the first direction (the X-axis direction) in the first portion 14a, the third portion 14c, and the fifth portion 14e of the quantum cascade laser 14. Preferably, the length of the electrode 29 in the first portion 14a and the fifth portion 14e of the quantum cascade laser 14 in the first direction (the X-axis direction) is equal to or greater than the length of the electrode 29 in the third portion 14c of the quantum cascade laser 14. Thus, the electrode 29 having a length that is approximately equal to or greater than the length of the electrode 29 on the semiconductor mesa 17 is formed on each of the first portion 14a and the fifth portion 14e. Accordingly, heat generated in the semiconductor mesa 17 is dissipated through these portions of the electrode (the electrode 29 on the first portion 14a and the fifth portion 14e) to the first area 16b and the third area 16d of the sub-mount 16.

In the semiconductor optical device assembly 12, the electrode 29 extends in the first direction (the X-axis direction) in the second portion 14b and the fourth portion 14d of the quantum cascade laser 14. Preferably, the length of the electrode 29 in the second portion 14b and the fourth portion 14d of the quantum cascade laser 14 in the first direction (the X-axis direction) is equal to or greater than the length of the electrode 29 in the third portion 14c. The substrate 19 includes a first cladding region made of a semiconductor of the first conductive type. The semiconductor layer 21b of the semiconductor mesa 17 includes a second cladding region made of a semiconductor of the first conductive type. Side surfaces of the first cladding region, the light emitting layer, and the second cladding region, are located at side surfaces of the trenches 25a and 25b. The quantum cascade laser 14 includes the insulating layer 31, which serves as a protective film, disposed between the electrode 29 and the stacked semiconductor layer 23. The electrode 29 extends along the insulating layer 31 on the side surfaces of the trenches 25a and 25b. The thickness of the insulating layer 31 is, for example, 100 nm or greater and 500 nm or less.

According to the semiconductor optical device assembly 12, the side surfaces of the first cladding region, the light emitting layer, and the second cladding region in the semiconductor mesa 17 reach the side surfaces of the trenches 25a and 25b. Hence, heat generated in these semiconductor regions of the semiconductor mesa 17 is transferred through the insulating layer 31 to the electrode 29 on the side surfaces of the trenches.

In the semiconductor optical device assembly 12, preferably, the gap GAP is, for example, 5 μm or greater. This is because the thickness of the AuSn solder is about 3 μm, and the AuSn solder becomes slightly melted and flows when heated. The trenches 25a and 25b reach the first cladding region of the substrate 19, which is located below the light emitting layer 21a. Preferably, the substrate 19 is made of InP. The sub-mount 16 is made of AlN or the like. According to the semiconductor optical device assembly 12, because the gap GAP is set to be 5 μm or greater, the gap GAP is easily formed in the manufacturing process.

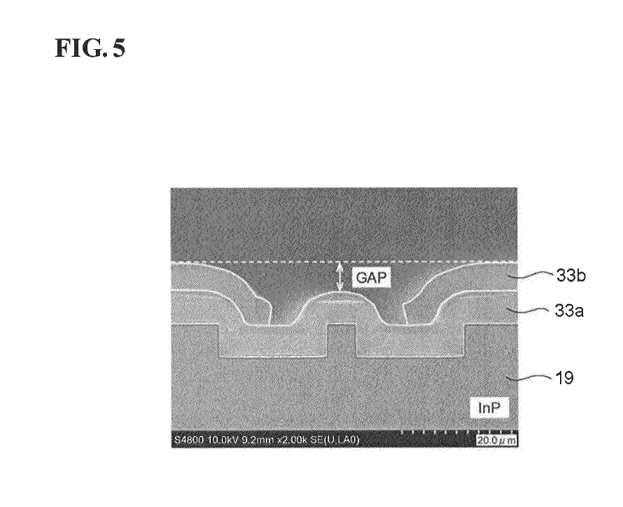

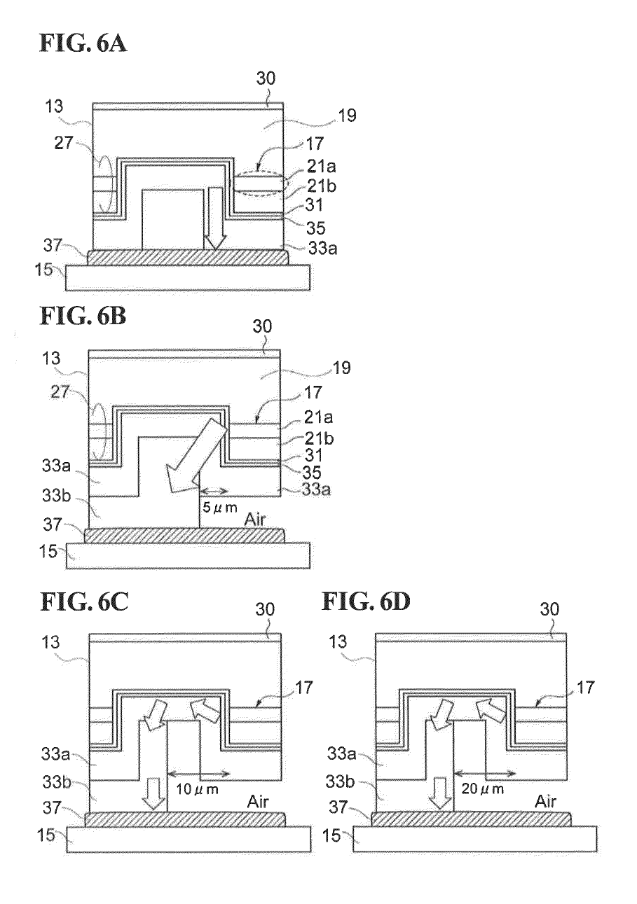

FIG. 5 shows a scanning electron microscope (SEM) image of a quantum cascade laser according to the present embodiment. In order to estimate the heat dissipation performance of such a quantum cascade laser, thermal analyses are performed on models of the quantum cascade laser. FIGS. 6A to 6D illustrate examples of a quantum cascade laser according to the present embodiment used in thermal analyses. Table shows the results of thermal analyses performed on the structures shown in FIGS. 6A to 6D. Referring to FIGS. 6A to 6D, the structures for the thermal analyses 1 to 4 will be described. Table shows the results of thermal analysis simulations each performed by using a device model corresponding to the left half portion of the device on the left side of the center of the semiconductor mesa, which has a width of 250 μm.

TABLE

| | Thermal | Thermal | Thermal | Thermal |
|---|---|---|---|---|
| | analysis 1 | analysis 2 | analysis 3 | analysis 4 |
| | Single- | Double-layer | Double-layer | Double-layer |
| | layer | plating | plating | plating |
| | plating | (5 μm) | (10 μm) | (20 μm) |
| Core temperature | 377.2 | 379.7 | 383.8 | 385.7 |
| [K] | | | | |
| Temperature | — | 2.5 | 6.6 | 8.5 |
| difference from | | (+0.7%) | (+1.8%) | (+2.3%) |
| thermal analysis 1 | | | | |
| [K] | | | | |

FIGS. 6A to 6D respectively illustrate thermal analyses 1 to 4. In FIG. 6A to 6D, the arrows indicate heat dissipation paths. The thickness of the first plating layer is 5 μm. The thickness of the second plating layer is 5 μm. The thickness of the protective film (SiN film) is 0.3 μm. The thermal conductivity of the semiconductor (InP) is represented by 2.31×10³×T^{1.45} (W/K·cm), where T is the temperature (kelvin). The thermal conductivity of the plating metal is 3.37−6.6×10⁻⁴×T (W/K·cm). The thermal conductivity of the protective film is −1.4×10⁴×T+0.3 (W/K·cm). The depth of the trench is 6 μm.

### Thermal Analysis 1 (FIG. 6A)

In the structure for thermal analysis 1, the electrode on the upper surface of the semiconductor mesa is connected to the sub-mount through the solder member.

### Thermal Analysis 2 (FIG. 6B)

In the structure for thermal analysis 2, the electrode on the upper surface of the semiconductor mesa is not connected to the sub-mount through the solder member, and an edge of the second plating layer is separated from the side surface of the semiconductor mesa by a distance of 5 μm. The edge of the second plating layer is formed so as to be in contact with the first plating layer on the side surface of the semiconductor mesa (the trench is filled with the plating layers).

Thermal Analysis 3 (FIG. 6C)

In the structure for thermal analysis 3, the electrode on the upper surface of the semiconductor mesa is not connected to the sub-mount through the solder member, and an edge of the second plating layer is separated from the side surface of the semiconductor mesa by a distance of 10 μm. To obtain this gap, the trench has a width larger than that of the structure for thermal analysis 2 by 5 μm. The edge of the second plating layer is separated from the first plating layer on the side surface of the semiconductor mesa by a distance of 5 μm.

### Thermal Analysis 4 (FIG. 6D)

In the structure for thermal analysis 4, the electrode on the upper surface of the semiconductor mesa is not connected to the sub-mount via the solder member, and an edge of the second plating layer is separated from the side surface of the semiconductor mesa by a distance of 20 μm. To obtain this gap, the trench has a width larger than that of the structure for thermal analysis 2 by 15 μm. The edge of the second plating layer is separated from the first plating layer on the side surface of the semiconductor mesa by a distance of 15 μm.

As a condition for the thermal analysis simulation, it is assumed that the heat generated from the active layer is 5 W.

Core temperature of the model of thermal analysis 1: 377.2K (absolute temperature, kelvin)

Core temperature of the model of thermal analysis 2: 379.7K

Core temperature of the model of thermal analysis 3: 383.8K

Core temperature of the model of thermal analysis 4: 385.7K

Comparison of the simulation results is as follows. The difference and the ratio of increase from the core temperature 377.2K of the model for thermal analysis 1 are shown below.

Increase ratio (temperature difference) of the core temperature of the model of thermal analysis 2: +0.7% (2.5K)

Increase ratio (temperature difference) of the core temperature of the model of thermal analysis 3: +1.8% (6.6K)

Increase ratio (temperature difference) of the core temperature of the model of thermal analysis 4: +2.3% (8.5K)

Increase ratio (temperature difference) of the core temperature of a model having a face-up configuration: +8% (30K)

This comparison shows high heat-dissipation performances of the models for thermal analysis 2, thermal analysis 3, and thermal analysis 4.

As heretofore described, in a quantum cascade laser that is mounted in a face-down configuration, an air gap GAP is formed between a mesa portion and a mount base member. Thus, a stress is not directly applied to the mesa portion, because the mesa portion is not in direct contact with the mount base member. By using a mounting structure according to the present embodiment, a quantum cascade laser having good heat dissipation performance can be provided.

As compared with a semiconductor laser using for optical fiber communications, the electric power consumption of a quantum cascade laser is higher and the volume of the active layer is larger. Therefore, a quantum cascade laser is easily affected by a thermal stress from a sub-mount or a solder when the quantum cascade laser is mounted with its face down. A quantum cascade laser has a structure in which a plurality of quantum well structures are stacked. Hence, a quantum cascade laser requires a high operating voltage of about 10 volts. Moreover, the threshold current (driving current) is as high as about 1 ampere. For such operational reasons, the amount of heat generated by a light emitting layer is estimated to be about several tens of watts. This value is considerably larger than that of a semiconductor laser using for optical fiber communications.

The oscillation wavelength of a quantum cascade laser is as long as about 3 μm to 20 μm. A light emitting layer has a stacked structure, and the thickness of the light emitting layer is as large as 1 μm to 1.5 μm. The width of the light emitting layer is about 10 μm to 20 μm. Moreover, the mesa height of a light emitting portion is as large as 5 μm to 7 μm. Therefore, the volume of the light emitting layer is large. Moreover, as compared with a semiconductor laser for optical fiber communications, the gain per unit length is small. Hence, to obtain a gain for laser oscillation, a quantum cascade laser has a cavity length of 2 mm to 5 mm, and this is considerably larger than 300 μm (0.3 mm), which is the typical cavity length of a semiconductor laser for optical fiber communications. A quantum cascade laser has these structural characteristics. When a stress is applied to a semiconductor mesa from a solder member or the like, the semiconductor mesa is greatly affected by the stress due to such structural characteristics. As described above, a quantum cascade laser requires a high driving electric power and generates a large amount of heat. The present embodiment enables face-down mounting, with which the heat dissipation performance is improved as compared with face-up mounting. Moreover, in the quantum cascade laser according to the present embodiment, a stress is not directly applied to the semiconductor mesa in the mounting process. Specifically, a thermal stress is not applied to the active layer due to the difference between the thermal expansion coefficients of the sub-mount and the semiconductor. As a result, in a quantum cascade laser mounted with its face down, degradation of the characteristics and decrease in the reliability due to the stress such as a thermal stress can be avoided.

For a quantum cascade laser, which generates a large amount of heat, it is important to increase the heat dissipation performance by mounting the quantum cascade laser with its face down. However, due to the aforementioned structural reasons related to the light emitting portion, when a quantum cascade laser is mounted with its face down, the quantum cascade laser is easily affected by a stress such as a thermal stress.

According to the present embodiment, a stress applied to the semiconductor mesa is reduced in the mounting process or during operation while maintaining good heat dissipation performance.

The present invention is not limited to specific structures disclosed in the present embodiment.

What is claimed is:

1. A semiconductor optical device assembly comprising:
a quantum cascade laser including a first portion, a second portion, a third portion, a fourth portion, and a fifth portion that are sequentially arranged in a first direction; and
a sub-mount having a mount surface including a first area, a second area, and a third area that are sequentially arranged in the first direction, the first area and the third area supporting the first portion and the fifth portion of the quantum cascade laser,
wherein the quantum cascade laser includes:
a substrate having a main surface, the substrate being made of a first conductive type semiconductor;
a semiconductor mesa disposed on the main surface of the substrate in the third portion, the semiconductor mesa extending in a second direction that intersects the first direction, the semiconductor mesa including a light emitting layer and a first conductive type semiconductor layer disposed on the light emitting layer; and
an electrode extending in the first portion, the second portion, the third portion, the fourth portion, and the fifth portion of quantum cascade laser, the electrode being in contact with an upper surface of the semiconductor mesa,
wherein the electrode in the first portion and the fifth portion of the quantum cascade laser is in contact with the first area and the third area of the sub-mount, and
the quantum cascade laser is mounted on the sub-mount with a gap formed between a surface of the electrode of the third portion of the quantum cascade laser and the second area of the sub-mount.

2. The semiconductor optical device assembly according to claim 1,
wherein the quantum cascade laser includes a trench in each of the second portion and the fourth portion,
the trench extends in the second direction, and
the semiconductor mesa is defined by the trenches in the second portion and the fourth portion.

3. The semiconductor optical device assembly according to claim 1,
wherein the quantum cascade laser includes an insulating layer disposed on the substrate and on a side surface and the upper surface of the semiconductor mesa,
the electrode is disposed on the insulating layer,
the insulating layer has an opening on the upper surface of the semiconductor mesa, and
the electrode is in contact with the upper surface of the semiconductor mesa through the opening of the insulating layer.

4. The semiconductor optical device assembly according to claim 3,
wherein the quantum cascade laser includes terrace portions disposed on the main surface of the substrate in the first portion and the fifth portion, respectively,
the terrace portion includes the light emitting layer and the first conductive type semiconductor layer,
the insulating layer is disposed on the terrace portion, and
the quantum cascade laser has a distance between the main surface of the substrate and the insulating layer in the first portion and the fifth portion that is substantially equal to a distance between the main surface of the substrate and the electrode in the third portion.

5. The semiconductor optical device assembly according to claim 1,
wherein the electrode in the first portion and the fifth portion of the quantum cascade laser has a thickness greater than a thickness of the electrode in the third portion of the quantum cascade laser.

6. The semiconductor optical device assembly according to claim 1,
wherein the electrode in the third portion of the quantum cascade laser includes a first plating layer,
the electrode in the first portion and the fifth portion of the quantum cascade laser includes the first plating layer and a second plating layer disposed on the first plating layer, and
the gap is formed between the first plating layer in the third portion of the quantum cascade laser and the second area of the sub-mount.

7. The semiconductor optical device assembly according to claim 1,
wherein the second area of the sub-mount includes a groove that is recessed from surfaces of the first area and the third area, and
the semiconductor mesa of the quantum cascade laser is aligned with the groove.

8. The semiconductor optical device assembly according to claim 1, further comprising:
a solder member disposed on each of the first area and the third area of the sub-mount,
wherein the first portion and the fifth portion of the quantum cascade laser are supported by the first area and the third area of the sub-mount via the solder member.

9. The semiconductor optical device assembly according to claim 1,
wherein the electrode extends in the first direction in the first portion, the third portion, and the fifth portion of the quantum cascade laser, and
the electrode in the first portion and the fifth portion of the quantum cascade laser has a length that is equal to or greater than a length of the electrode in the third portion of the quantum cascade laser in the first direction.

10. The semiconductor optical device assembly according to claim 1,
wherein the quantum cascade laser further includes:
a trench in each of the second portion and the fourth portion, the trench defining the semiconductor mesa, and
an insulating layer disposed on the substrate, a side surface of the trench, and a side surface and the upper surface of the semiconductor mesa, the insulating layer having an opening on the upper surface of the semiconductor mesa,
wherein the electrode is formed on the insulating layer, the electrode being contact with the upper surface of the semiconductor mesa through the opening, and
the electrode in the second portion and the fourth portion of the quantum cascade laser has a length that is equal to or greater than a length of the electrode in the third portion of the quantum cascade laser in the first direction.

11. The semiconductor optical device assembly according to claim 10,
wherein the substrate of the quantum cascade laser includes a first cladding region made of the first conductive type semiconductor,
the first conductive type semiconductor layer of the semiconductor mesa includes a second cladding region,
the trench reaches the first cladding region of the substrate, and
the first cladding region, the light emitting layer, and the second cladding region are located at the side surface of the trench.

12. The semiconductor optical device assembly according to claim 1,
wherein the semiconductor mesa has a width in the range of 5 μm to 20 μm,
the substrate is made of InP, and
the sub-mount is made of AlN.
